(19) United States
(12) Patent Application Publication
(10) Pub. No.: US 2015/0102379 A1
(43) Pub. Date: Apr. 16, 2015

(54) LIGHT EMITTING DIODE STRUCTURE

(71) Applicant: Genesis Photonics Inc., Tainan City (TW)

(72) Inventors: Yun-Li Li, Taipei City (TW); Jing-En Huang, Tainan City (TW); Shao-Ying Ting, Tainan City (TW); Chih-Ling Wu, New Taipei City (TW); Yi-Ru Huang, Tainan City (TW); Yu-Yun Lo, Tainan City (TW)

(21) Appl. No.: 14/513,228

(22) Filed: Oct. 14, 2014

(30) Foreign Application Priority Data
Oct. 14, 2013 (TW) 102136996

(51) Int. Cl. H01L 33/58; H01L 33/36

(52) U.S. Cl. CPC H01L 33/58; H01L 33/36
USPC 257/98

(57) ABSTRACT

A light emitting diode structure includes a substrate and a light emitting unit. The substrate has a protrusion portion and a light guiding portion. The protrusion portion and the light guiding portion have a seamless connection therebetween, and a horizontal projection area of the protrusion portion is smaller than that of the light guiding portion. The light emitting unit is disposed on the protrusion portion of the substrate. The light emitting unit is adapted to emit a light beam, and a portion of the light beam enters the light guiding portion from the protrusion portion and emits from an upper surface of the light guiding portion uncovered by the protrusion portion.

### CROSS-REFERENCE TO RELATED APPLICATION

This application claims the priority benefit of Taiwan application serial no. 102136996, filed on Oct. 14, 2013. The entirety of the above-mentioned patent application is hereby incorporated by reference herein and made a part of this specification.

### BACKGROUND OF THE INVENTION

1. Field of the Invention

The invention relates to a semiconductor structure, and more particularly, to a light emitting diode structure.

2. Description of Related Art

In general, when a light emitting diode structure is driven to emit light, due to the fact that reflected angles and reflected degrees of the light by a flat-block-shaped substrate are limited, which means that the flat-block-shaped substrate may result in smaller light-emitting angles (about 80 degrees) of the light emitting diode structure, a light extraction efficiency of the light emitting diode structure may be unable to be enhanced. In order to solve the above problems, a conventional roughening treatment is carried out to the side walls of the substrate. However, since the substrate is closer to the light emitting unit, the light emitting unit may be more likely to be damaged during the process of the roughening treatment, which may instead more likely to make the brightness of the light emitting diode structure to reduce. Accordingly, how to further effectively enhance the light extraction efficiency of the light emitting diode structure by structural design without increasing the cost and change of material is indeed an important issue.

### SUMMARY OF THE INVENTION

The invention provides a light emitting diode structure, which has a larger light-emitting angle and a better light-emitting efficiency.

The invention provides a light emitting diode structure, which includes a substrate and a light emitting unit. The substrate has a protrusion portion and a light guiding portion, wherein the protrusion portion and the light guiding portion have a seamless connection therebetween, and a horizontal projection area of the protrusion portion is smaller than a horizontal projection area of the light guiding portion. The light emitting unit is disposed on the protrusion portion of the substrate, wherein the light emitting unit is adapted to emit a light beam, and a portion of the light beam enters the light guiding portion from the protrusion portion and emits from an upper surface of the light guiding portion uncovered by the protrusion portion.

In an embodiment of the invention, the light emitting unit includes a first type semiconductor layer, a light emitting layer, and a second type semiconductor layer. The first type semiconductor layer is disposed on the protrusion portion of the substrate, the light emitting layer covers a portion of the first type semiconductor layer, and the second type semiconductor layer is disposed on the light emitting layer.

In an embodiment of the invention, the light emitting diode structure further includes a first electrode and a second electrode. The first electrode is disposed on the first type semiconductor layer uncovered by the light emitting layer. The second electrode is disposed on the second type semiconductor layer, wherein the first electrode and the second electrode are located on one same side of the substrate.

In an embodiment of the invention, a thickness of the protrusion portion of the substrate is smaller than a thickness of the light guiding portion of the substrate.

In an embodiment of the invention, the thickness of the light guiding portion of the substrate is 100 times to 200 times of the thickness of the protrusion portion of the substrate.

In an embodiment of the invention, the horizontal projection area of the light guiding portion of the substrate is 1.1 times to 10 times of the horizontal projection area of the protrusion portion of the substrate.

In an embodiment of the invention, the light guiding portion of the substrate has a lower surface which is opposite to the upper surface and a side surface which connects the upper surface and the lower surface.

In an embodiment of the invention, the upper surface of the light guiding portion is a rough surface.

In an embodiment of the invention, the side surface of the light guiding portion is a rough surface.

In an embodiment of the invention, the upper surface and the side surface of the light guiding portion are both rough surfaces.

In an embodiment of the invention, between the side surface and a normal direction of the lower surface has an angle, and the angle is between 10 to 80 degrees.

In an embodiment of the invention, the side surface comprises a chamfered plane and a vertical plane, wherein the chamfered plane connects the upper surface and the vertical plane, and the vertical plane connects the chamfered plane and the lower surface.

According to the above, the protrusion portion and the light guiding portion of the substrate of the invention have a seamless connection therebetween, and the horizontal projection area of the protrusion portion is smaller than that of the light guiding portion, meaning that the substrate of the invention may be regarded as a convex substrate. Thus, by a light-guiding effect of the light guiding portion, a range of the light-emitting angle of the portion of the light beam emitted from the light emitting unit may be broadened. Accordingly, the light emitting diode structure of the invention may have the larger light-emitting angle and the better light-emitting efficiency.

In order to make the aforementioned and other features and advantages of the invention comprehensible, embodiments accompanied with figures are described in detail below.

### BRIEF DESCRIPTION OF THE DRAWINGS

FIG. 1 illustrates a cross-sectional schematic diagram of a light emitting diode structure according to an embodiment of the invention.

FIG. 2 illustrates a cross-sectional schematic diagram of a light emitting diode structure according to another embodiment of the invention.

FIG. 3 illustrates a cross-sectional schematic diagram of a light emitting diode structure according to another embodiment of the invention.

FIG. 4 illustrates a cross-sectional schematic diagram of a light emitting diode structure according to another embodiment of the invention.

### DESCRIPTION OF EMBODIMENTS

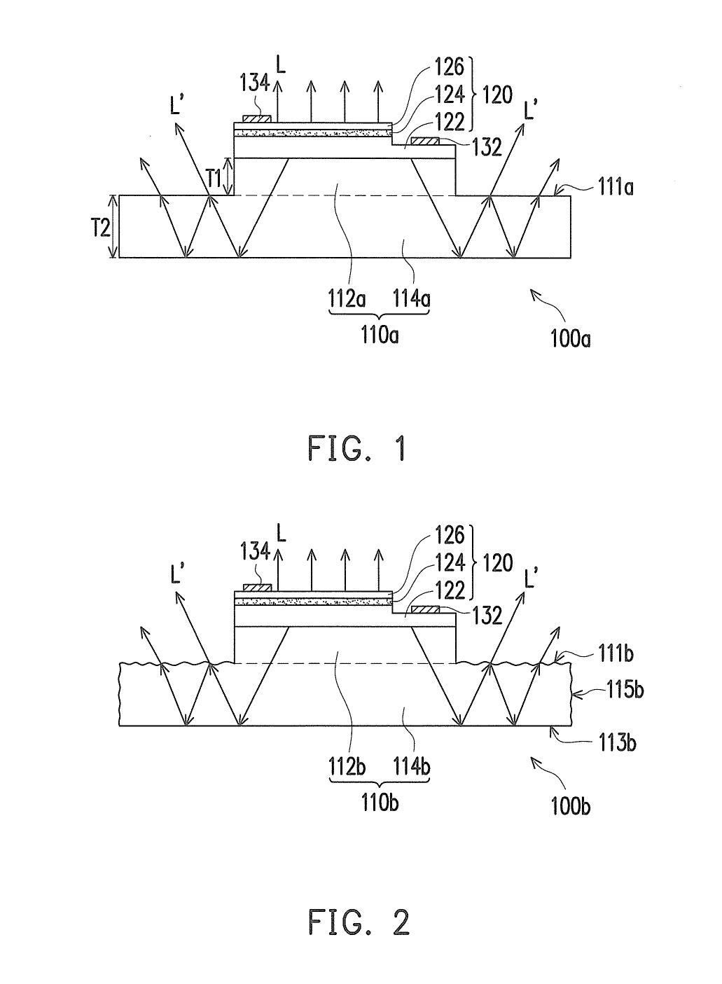

FIG. 1 illustrates a cross-sectional schematic diagram of a light emitting diode structure according to an embodiment of the invention. Please refer to FIG. 1. In the present embodiment, a light emitting diode structure 100a includes a substrate 110a and a light emitting unit 120. The substrate 110a has a protrusion portion 112a and a light guiding portion 114a. The protrusion portion 112a and the light guiding portion 114a have a seamless connection therebetween. A horizontal projection area of the protrusion portion 112a is smaller than a horizontal projection area of the light guiding portion 114a. The light emitting unit 120 is disposed on the protrusion portion 112a of the substrate 110a. The light emitting unit 120 is adapted to emit a light beam L. A portion of the light beam L′ enters the light guiding portion 114a from the protrusion portion 112a, and the portion of the light beam L′ emits from an upper surface 111a of the light guiding portion 114a uncovered by the protrusion portion 112a.

More specifically, in the present embodiment, a thickness T1 of the protrusion portion 112a of the substrate 110a is smaller than a thickness T2 of the light guiding portion 114a. The thickness T2 of the light guiding portion 114a of the substrate 110a is more than 1 times of the thickness T1 of the protrusion portion 112a. Preferably, an optimal ratio of the thickness T2 of the light guiding portion 114a of the substrate 110a to the thickness T1 of the protrusion portion 112a is 100 times to 200 times. Preferably, the horizontal projection area of the light guiding portion 114a of the substrate 110a is 1.1 times to 10 times of the horizontal projection area of the protrusion portion 112a of the substrate 110a. An optimal ratio of the horizontal projection area of the light guiding portion 114a of the substrate 110a to the horizontal projection area of the protrusion portion 112a is 1.5 times to 5 times. It should be noted that, if the ratio of the horizontal projection area is smaller than 1.1 times, the light-guiding effect of the light guiding portion 114a may become ineffective, which is unable to effectively expand the light-emitting angle of the light emitting unit 120. Or, if the ratio of the horizontal projection area is greater than 10 times, the area of the light guiding portion 114a in the light emitting diode structure 100a may become too large for performing subsequent wire bonding and die bonding processes. Material of the substrate 110a herein may be such as sapphire, aluminum nitride, or glass.

In addition, in the present embodiment, the light emitting unit 120 includes a first type semiconductor layer 122, a light emitting layer 124, and a second type semiconductor layer 126. The first type semiconductor layer 122 is disposed on the protrusion portion 112a of the substrate 110a. The light emitting layer 124 covers a portion of the first type semiconductor layer 122. The second type semiconductor layer 126 is disposed on the light emitting layer 124. Moreover, the light emitting diode structure 100a in the present embodiment further includes a first electrode 132 and a second electrode 134. The first electrode 132 is disposed on the first type semiconductor layer 122 uncovered by the light emitting layer 124. The second electrode 134 is disposed on the second type semiconductor layer 126. The first electrode 132 and the second electrode 134 are located on one same side of the substrate 110a.

Due to the fact that the protrusion portion 112a and the light guiding portion 114a of the substrate 110a in the present embodiment have a seamless connection therebetween (that is, integrally formed), and the horizontal projection area of the protrusion portion 112a is smaller than the horizontal projection area of the light guiding portion 114a, the substrate 110a in the present embodiment may be regarded as a convex substrate. Thus, by the light-guiding effect of the light guiding portion 114a, the range of the light-emitting angle of the portion of the light beam L′ emitted from the light emitting unit 120 may be broadened. Accordingly, the light emitting diode structure 100a in the present embodiment may have the larger light-emitting angle and the better light-emitting efficiency.

It should be noted herein that, the reference numerals and parts of the contents in the above embodiment are used in the following embodiments. The same or similar components are represented as the same reference numerals, and description of the same technical contents are omitted. The above embodiment may be referred to for the omitted parts of the description, which are not repeated in the following embodiments.

FIG. 2 illustrates a cross-sectional schematic diagram of a light emitting diode structure according to another embodiment of the invention. Please refer to FIG. 2. A light emitting diode structure 100b in the present embodiment is similar to the light emitting diode structure 100a in FIG. 1, wherein the main difference therebetween is that the light extraction ratio of the light emitting diode structure 100b in the present embodiment may be increased through a roughening treatment. In detail, in the present embodiment, a light guiding portion 114b of a substrate 110b has an upper surface 111b and a lower surface 113b which are opposite to each other, and a side surface 115b which connects the upper surface 111b and the lower surface 113b. The upper surface 111b of the light guiding portion 114b may be a rough surface. Or, the side surface 115b of the light guiding portion 114b may be a rough surface. Moreover, the upper surface 111b and the side surface 115b of the light guiding portion 114b may both be rough surfaces. Herein, a center-line average roughness of the rough surface is between 100 nm to 3000 nm. Preferably, the rough surface is a periodically-patterned surface, but the invention is not limited thereto.

In the present embodiment, the upper surface 111b and the side surface 115b of the light guiding portion 114b are both rough surfaces. Thus, in addition to the light-guiding effect, the light guiding portion 114b may also have a scattering effect, which may scatter the light beam of the light emitting unit 120 which enters the light guiding portion 114b from the protrusion portion 112b, whereby broadening the range of the light-emitting angle of the light emitting unit 120. Accordingly, the light emitting diode structure 100b of the invention may have the larger light-emitting angle and the better light-emitting efficiency. Furthermore, as compared to the protrusion portion 112b, the upper surface 111b and the side surface 115b of the light guiding portion 114b are located relatively far away from the light emitting unit 120, so that the roughening treatment to the upper surface 111b and the side surface 115b may not affect the light-emitting efficiency of the light emitting unit 120.

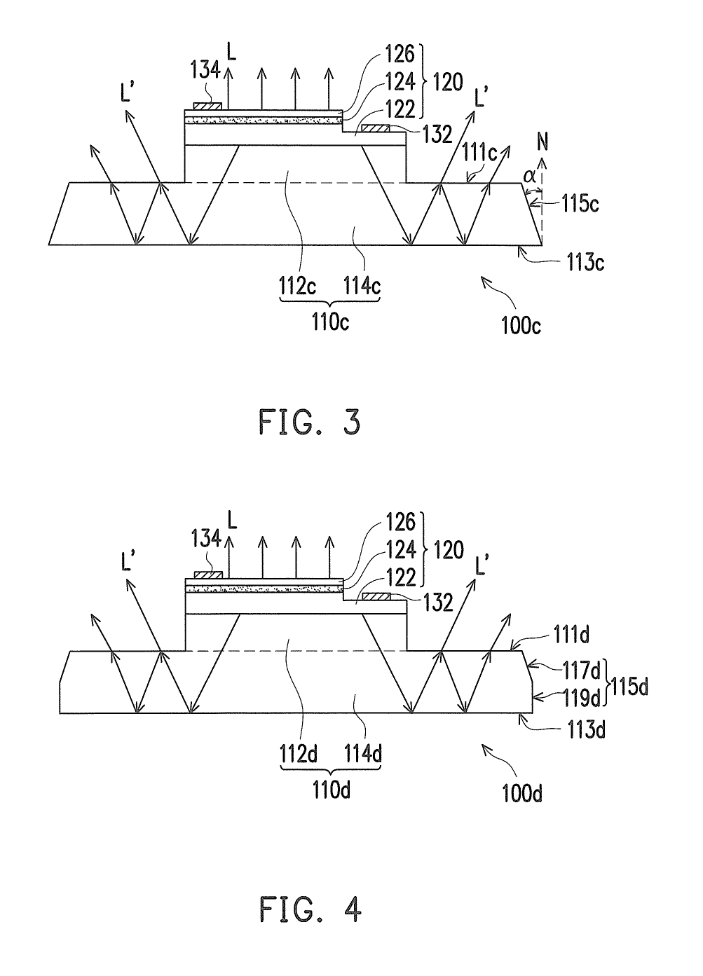

FIG. 3 illustrates a cross-sectional schematic diagram of a light emitting diode structure according to another embodiment of the invention. Please refer to FIG. 3. A light emitting diode structure 100c in the present embodiment is similar to the light emitting diode structure 100a in FIG. 1, wherein the main difference therebetween is that the substrate 110c in the present embodiment has an upper surface 111c and a lower surface 113c which are opposite to each other, and a side surface 115c which connects the upper surface 111c and the lower surface 113c, wherein between the side surface 115c and a normal direction N of the lower surface 113c has an angle α, and the angle α is between 10 to 80 degrees, which may effectively increase the light-emitting efficiency of the light emitting unit 120. Herein, an exterior contour of the protrusion portion 112c of the substrate 110c is embodied into a rectangle, and an exterior contour of the light guiding portion 114c of the substrate 110c is embodied into a trapezoid.

FIG. 4 illustrates a cross-sectional schematic diagram of a light emitting diode structure according to another embodiment of the invention. Please refer to FIG. 4. A light emitting diode structure 100d in the present embodiment is similar to the light emitting diode structure 100a in FIG. 1, wherein the main difference therebetween is that the substrate 110d in the present embodiment has an upper surface 111d and a lower surface 113d which are opposite to each other, and a side surface 115d which connects the upper surface 111d and the lower surface 113d. The side surface 115d includes a chamfered plane 117d and a vertical plane 119d. The chamfered plane 117d connects the upper surface 111d and the vertical plane 119d. The vertical plane 119d connects the chamfered plane 117d and the lower surface 113d. It should be noted that, the design of the side surface 115d of the light guiding portion 114d of the substrate 110d may effectively increase the light-emitting efficiency of the light emitting unit 120, and may improve the mechanical strength at the edge of the substrate 110d, so as to avoid defects caused by stress concentration. Herein, an exterior contour of the protrusion portion 112d of the substrate 110d is embodied into a rectangle, and an exterior contour of the light guiding portion 114d of the substrate 110d is embodied into a rectangle with chamfered structures.

In addition, in other embodiments which are not illustrated herein, in order to further increase the light-emitting angle and the light-emitting efficiency, the light guiding portion 114b with the rough surfaces (referring to FIG. 2), the light guiding portion 114c with the inclined planes (referring to FIG. 3), or the light guiding portion 114d with the chamfer (referring to FIG. 4) as mentioned in the above embodiments may also be selected to use. In order to achieve the desired technical effects, those skilled in the art may select the above components by referring to the description in the above embodiments based on the actual demand.

According to the above, the protrusion portion and the light guiding portion of the substrate of the invention have a seamless connection therebetween, and the horizontal projection area of the protrusion portion is smaller than that of the light guiding portion, meaning that the substrate of the invention may be regarded as a convex substrate. Thus, by a light-guiding effect of the light guiding portion, a range of the light-emitting angle of the portion of the light beam emitted from the light emitting unit may be broadened. Accordingly, the light emitting diode structure of the invention may have the larger light-emitting angle and the better light-emitting efficiency.

It will be apparent to those skilled in the art that various modifications and variations can be made to the structure of the disclosed embodiments without departing from the scope or spirit of the invention. In view of the foregoing, it is intended that the disclosure cover modifications and variations of this specification provided they fall within the scope of the following claims and their equivalents.

What is claimed is:

1. A light emitting diode structure, comprising:
a substrate, having a protrusion portion and a light guiding portion, wherein the protrusion portion and the light guiding portion have a seamless connection therebetween, and a horizontal projection area of the protrusion portion is smaller than a horizontal projection area of the light guiding portion; and
a light emitting unit, disposed on the protrusion portion of the substrate, wherein the light emitting unit is adapted to emit a light beam, and a portion of the light beam enters the light guiding portion from the protrusion portion and emits from an upper surface of the light guiding portion uncovered by the protrusion portion.

2. The light emitting diode structure as claimed in claim 1, wherein the light emitting unit comprises a first type semiconductor layer, a light emitting layer, and a second type semiconductor layer, the first type semiconductor layer is disposed on the protrusion portion of the substrate, the light emitting layer covers a portion of the first type semiconductor layer, and the second type semiconductor layer is disposed on the light emitting layer.

3. The light emitting diode structure as claimed in claim 2, further comprising:
a first electrode, disposed on the first type semiconductor layer uncovered by the light emitting layer; and
a second electrode, disposed on the second type semiconductor layer, wherein the first electrode and the second electrode are located on one same side of the substrate.

4. The light emitting diode structure as claimed in claim 1, wherein a thickness of the protrusion portion of the substrate is smaller than a thickness of the light guiding portion of the substrate.

5. The light emitting diode structure as claimed in claim 4, wherein the thickness of the light guiding portion of the substrate is 100 times to 200 times of the thickness of the protrusion portion of the substrate.

6. The light emitting diode structure as claimed in claim 1, wherein the horizontal projection area of the light guiding portion of the substrate is 1.1 times to 10 times of the horizontal projection area of the protrusion portion of the substrate.

7. The light emitting diode structure as claimed in claim 1, wherein the light guiding portion of the substrate has a lower surface which is opposite to the upper surface and a side surface which connects the upper surface and the lower surface.

8. The light emitting diode structure as claimed in claim 7, wherein the upper surface of the light guiding portion is a rough surface.

9. The light emitting diode structure as claimed in claim 7, wherein the side surface of the light guiding portion is a rough surface.

10. The light emitting diode structure as claimed in claim 7, wherein the upper surface and the side surface of the light guiding portion are both rough surfaces.

11. The light emitting diode structure as claimed in claim 7, wherein between the side surface and a normal direction of the lower surface has an angle, and the angle is between 10 to 80 degrees.

12. The light emitting diode structure as claimed in claim 7, wherein the side surface comprises a chamfered plane and a vertical plane, the chamfered plane connects the upper surface and the vertical plane, and the vertical plane connects the chamfered plane and the lower surface.
